(19) United States
(12) Patent Application Publication
(10) Pub. No.: US 2012/0244441 A1
(43) Pub. Date: Sep. 27, 2012

(54) SILICON FILM AND LITHIUM SECONDARY BATTERY

(75) Inventors: Suguru Noda, Bunkyo-ku (JP); Shingo Morokuma, Bunkyo-ku (JP); Taketsugu Yamamoto, Tsukuba-shi (JP)

(73) Assignees: THE UNIVERSITY OF TOKYO, Bunkyo-ku, Tokyo (JP); SUMITOMO CHEMICAL COMPANY, LIMITED, Chuo-ku, Tokyo (JP)

(21) Appl. No.: 13/514,893

(22) PCT Filed: Dec. 10, 2010
(86) PCT No.: PCT/JP2010/072255

§ 371 Date: Jun. 8, 2012

(30) Foreign Application Priority Data
Dec. 10, 2009 (JP) 2009-280187

(51) Int. Cl. C01B 33/02; B32B 5/06; C23C 16/24; C23C 16/30; B32B 15/04; H01M 4/38; B82Y 30/00

(52) U.S. Cl. 429/218.1; 428/220; 428/221; 428/450; 427/248.1; 118/724; 423/348; 977/762

(57) ABSTRACT

Provided are a silicon film which can give an electrode suitable for use in high-capacity lithium secondary batteries, and a process for easily producing the silicon film. The silicon film comprises a columnar aggregate which is an aggregate of columnar structures made of Si or a Si compound. The silicon film may be a film wherein the diameter of the columnar structures is from 10 nm to 100 nm and the film thickness is from 0.2 μm to 100 μm. In the process for preparing a silicon film on a substrate by vapor deposition using a vapor deposition source made of Si or a Si compound, the temperature of the vapor deposition source is 1700 K or higher, the temperature of the substrate is lower than that of the vapor deposition source, and the temperature difference between the vapor deposition source and the substrate is 700 K or larger. In the process for preparing the silicon film, the distance (D) between the vapor deposition source and the substrate is shorter than the minimum diameter (P) of the substrate, the minimum diameter (P) being determined by viewing the substrate from the perpendicular direction. Also provided are an electrode comprising the silicon film, and a lithium secondary battery comprising the electrode as a negative electrode.

### TECHNICAL FIELD

The present invention relates to a silicon film and a lithium secondary battery. More specifically, the present invention relates to a silicon film obtained by vapor deposition, and a lithium secondary battery which uses an electrode having the silicon film as a negative electrode.

### BACKGROUND ART

Lithium secondary batteries are used as power sources for mobile devices, such as personal computers and mobile phones. Furthermore, Lithium secondary batteries have been recently tested as power sources for vehicles such as electric vehicles and hybrid electric vehicles which can reduce environmental burdens by CO₂.

In the art of lithium secondary batteries, silicon (Si) materials have been studied as materials for negative electrodes capable of storing and releasing lithium ions. Although carbonaceous materials are mainly used for negative electrodes at the present, Si negative electrodes have about 4200 mAh/g of theoretical discharge capacity which is more than ten times that of carbonaceous negative electrodes.

However, it is reported that, if a lithium secondary battery uses a Si negative electrode, secondary battery properties, such as cycle characteristics, deteriorate due to the large expansion and contraction coefficient of negative electrodes at the time of charge and discharge (Patent Document 1).

Patent Document 1 discloses that a silicon source is introduced into hot plasma to form an electrode having a silicon film made of silicon nanowire networks on a substrate, and the obtained electrode is used as a negative electrode of lithium secondary batteries. Gaps between the wires in the silicon film act as spaces for buffering the expansion caused when charging lithium secondary batteries, i.e., when storing lithium ions, and thereby decrease expansion and contraction coefficient of Si negative electrodes.

In addition, Patent Document 2 discloses that an electrode having silicon columnar structures made by etching a silicon substrate is used as a negative electrode for lithium secondary batteries. In this case, gaps between the silicon columnar structures act as spaces for buffering the expansion.

Furthermore, Patent Document 3 discloses that a silicon flat film is used as a negative electrode for a lithium secondary battery, and repeatedly charge and discharge the lithium secondary battery, and thereby cuts, i.e., gaps are formed in the silicon flat film. In this case, the cuts act as spaces for buffering the expansion.

Patent Document 1: JP-2008-269827-A

Patent Document 2: WO2004/042851

Patent Document 3: WO2001/031720

### DISCLOSURE OF THE INVENTION

### Problems to be Solved by the Invention

However, as described in Patent Document 1, although the use of nanowire-shaped silicon is effective in increasing the film thickness and decreasing expansion and contraction coefficients at the time of charge and discharge, it is difficult to increase the capacity of secondary batteries. This is because the gap between the wires occupies the major part of the silicon film, and thereby the density of silicon material in the electrode is low. In addition, it is difficult to control the gaps, since the silicon nanowires grow randomly.

In addition, as described in Patent Document 2, when the electrode having silicon columnar structures is made by etching the silicon substrate and is used as a negative electrode, it is difficult to roll the electrode to obtain lithium secondary batteries since the silicon also acts as the substrate. Consequently, it has a structural limitation, which makes it difficult to obtain large capacity secondary batteries.

Furthermore, even in Patent Document 3, it is difficult to precisely control the gaps in order to obtain large capacity secondary batteries, since the gaps are cut into the silicon flat film by charging and discharging secondary batteries.

An objective of the present invention is to provide a silicon film used in a preferable electrode for large capacity lithium secondary batteries, and the easy production process thereof.

### Means to Solve the Problems

The present inventors have continued intensive studies to attain the above-described object, and accomplished the present invention. That is, the present invention provides the following inventions.

<1> A silicon film, comprising a columnar aggregate which is an aggregate of columnar structures made of Si or a Si compound.

<2> The silicon film of <1>, wherein side faces of the columnar structures are in contact with each other to form the columnar aggregate.

<3> The silicon film of <1> or <2>, wherein the columnar structures grow in the direction of thickness of the silicon film.

<4> The silicon film of any one of <1> to <3>, wherein the aspect ratio of the columnar structures is 20 or more.

<5> The silicon film of any one of <1> to <4>, having a plurality of the columnar aggregates.

<6> The silicon film of any one of <1> to <5>, wherein the diameter of the columnar structures is from 1 nm to 100 nm and the film thickness is from 0.2 μm to 100 μm.

<7> The silicon film of any one of <1> to <6>, wherein gaps of 0.3 nm to 10 nm are present between the columnar aggregates in parallel to the columnar aggregates.

<8> The silicon film of any one of <1> to <7>, comprising a secondary columnar aggregate, which is an aggregate of the columnar aggregates, and having cracks of 0.01 μm to 3 μm width between the secondary columnar aggregates in parallel to the columnar aggregates, and the distance between the cracks of from 1 μm to 100 μm.

<9> The silicon film of any one of <1> to <8>, wherein the columnar structures are polycrystalline or amorphous.

<10> A silicon film, comprising a columnar aggregate which is an aggregate of columnar structures made of Si or a Si compound, the columnar structures having a structure of particles connected in a columnar shape.

<11> The silicon film of <10>, wherein the diameter of the particles is from 1 nm to 1000 nm.

<12> The silicon film of <10> or <11>, having a plurality of the columnar aggregates.

<13> The silicon film of any one of <1> to <12>, which is formed in contact with a substrate.

<14> The silicon film of <13>, wherein the material of the substrate comprises at least one element selected from the group consisting of copper, nickel, iron, cobalt, chromium, manganese, molybdenum, niobium, tungsten, titanium and tantalum.

<15> A process for preparing a silicon film on a substrate by vapor deposition using a vapor deposition source made of Si or a Si compound, wherein the temperature of the vapor deposition source is 1700 K or higher, the temperature of the substrate is lower than that of the vapor deposition source, and the temperature difference between the vapor deposition source and the substrate is 700 K or larger.

<16> The process for preparing the silicon film of <15>, wherein the distance (D) between the vapor deposition source and the substrate is shorter than the minimum diameter (P) of the substrate, the minimum diameter (P) being determined by viewing the substrate from the perpendicular direction.

<17> The process for preparing the silicon film of <15> or <16>, wherein the mean free path (λ) of Si atoms is shorter than the distance (D) between the vapor deposition source and the substrate.

<18> The process for preparing the silicon film of any one of <15> to <17>, wherein the mean free path (λ) of Si atoms is 1/10 or shorter of the distance (D) between the vapor deposition source and the substrate.

<19> The process for preparing the silicon film of any one of <15> to <18>, wherein the growth rate of the film is from 0.1 μm/min to 200 μm/min.

<20> The process for preparing the silicon film of any one of <15> to <19>, wherein the material of the substrate comprises at least one element selected from the group consisting of copper, nickel, iron, cobalt, chromium, manganese, molybdenum, niobium, tungsten, titanium and tantalum.

<21> A silicon-film vapor-deposition equipment for vapor-depositing a silicon film on a substrate by a vapor deposition source made of Si or a Si compound,

wherein the equipment comprises:

means for heating the vapor deposition source to a temperature of 1700 K or higher, and

means for cooling the substrate to make the temperature of the substrate lower than that of the vapor deposition source, and

the temperatures of the vapor deposition source and the substrate can be adjusted such that the difference therebetween becomes 700 K or larger.

<22> The silicon-film vapor-deposition equipment of <21>, wherein the minimum diameter (P) of the substrate can be set to longer than the distance (D) between the vapor deposition source and the substrate, the minimum diameter (P) being determined by viewing the substrate from the perpendicular direction.

<23> The silicon-film vapor-deposition equipment of <21> or <22>, further comprising a carrier gas supplying means, and capable of conducting a vapor deposition under an condition wherein the mean free path (λ) of Si atoms is shorter than the distance (D) between the vapor deposition source and the substrate.

<24> The silicon-film vapor-deposition equipment of any one of <21> to <23>, capable of adjusting the growth rate of the film to the range of 0.1 μm/min to 200 μm/min.

<25> An electrode comprising the silicon film of any one of <1> to <14>.

<26> The electrode of <25>, wherein the silicon film is formed in contact with a metal substrate.

<27> A lithium secondary battery, comprising the electrode of <25> or <26> as a negative electrode.

### Effects of the Invention

The present invention can provide a silicon film which can provide an electrode preferable for large capacity lithium secondary batteries, and an easy production process thereof.

The silicon film of the present invention can mitigate the expansion and contraction of the silicon film at the time of charge and discharge of lithium secondary batteries through the gaps between the columnar structures, the gaps between the columnar aggregates each of which is aggregates of the columnar structures, and/or the gaps between the secondary columnar aggregates each of which is an aggregate of the columnar aggregates. Therefore, the silicon film of the present invention can suppress the degradation of a silicon film as a negative electrode during the repeated charges and discharges of a lithium secondary battery. That is, the silicon film of the present invention can provide a lithium secondary battery with superior cycle characteristics.

Such a silicon film of the present invention can be applied to not only lithium secondary batteries but also other electrochemical storage devices such as lithium ion capacitors.

Furthermore, according to the process of the present invention for producing the silicon film, a silicon film with practically useful thickness can be prepared in a short time. In addition, the process of the invention is low in cost of equipments, etc., since it employs a vapor deposition method which does not necessarily require high vacuum condition. Furthermore, according to the process of the present invention, environmental burdens are reduced, since generations of by-products at the time of film production can be reduced. Therefore, the process of the present invention for producing a silicon film is industrially very advantageous.

### BRIEF DESCRIPTION OF THE DRAWINGS

FIG. 1 A SEM image showing the cross-sectional view of the silicon film according to an embodiment of the present invention (Example 1).

FIG. 2 A SEM image showing the surface of the silicon film according to an embodiment of the present invention (Example 1).

FIG. 3 A figure showing the cycle characteristics of lithium secondary battery according to Example 1 of the present invention.

FIG. 4 A figure showing the charge and discharge curves of lithium secondary battery according to Example 1 of the present invention.

FIG. 5 A figure showing the cycle characteristics of lithium secondary battery according to Example 2 of the present invention.

FIG. 6 A figure showing the cycle characteristics of lithium secondary battery according to Example 3 of the present invention.

FIG. 7 A figure showing the cycle characteristics of lithium secondary battery according to Example 5 of the present invention.

FIG. 8 A figure showing the charge and discharge curves of lithium secondary battery according to Example 5 of the present invention.

FIG. 9 A SEM image showing the surface of the silicon film according to an embodiment of the present invention (Example 7).

FIG. 10 A SEM image showing the surface of the silicon film according to an embodiment of the present invention (Example 7).

### MODE FOR CARRYING OUT THE INVENTION

The present invention provides a silicon film comprising a columnar aggregate which is an aggregate of columnar structures made of Si or a Si compound. In the silicon film of the present invention, the columnar structure is made of Si or a Si compound. The aspect ratio of the columnar structures is preferably 2 or more, 5 or more, 10 or more, 20 or more, 50 or more, or 100 or more. The upper limit of the aspect ratio is usually around 5000. In the columnar aggregate of the present invention, side faces of the columnar structures are in contact with each other. The silicon film of the present invention preferably has a plurality of the columnar aggregates.

In the present invention, in order to increase a capacity of the resultant lithium secondary batteries, the diameter of the columnar structures is preferably from 10 nm to 100 nm or 1 nm to 100 nm, and the film thickness thereof is preferably from 0.2 μm to 100 μm. The diameter of the columnar structures may be 15 nm or more, 20 nm or more, or 30 nm or more, and 90 nm or less, 80 nm or less, or 70 nm or less.

In the present invention, in order to improve the cycle characteristics of the resultant lithium secondary battery, gaps from 0.3 nm to 10 nm are preferably present between the columnar structures in parallel to the columnar structures.

In the present invention, in order to further improve the cycle characteristics of the resultant lithium secondary battery, between secondary columnar aggregates each of which is aggregates of the columnar aggregates, cracks of 0.01 μm to 3 μm width are preferably present in parallel to the columnar aggregate, and the distance between the cracks is preferably from 1 μm to 100 μm. In addition, the diameter and the width of the columnar aggregates are preferably from 10 μm to 100 μm.

In view of the cycle characteristics of the resultant lithium secondary battery, the columnar structures in the present invention are preferably polycrystalline or amorphous.

The present invention also provides a silicon film comprising a columnar aggregate which is an aggregate of columnar structures made of Si or a Si compound, and the columnar structures have a structure of particles connected in a columnar shape. The silicon film of the present invention preferably has a plurality of the columnar aggregates. In order to obtain lithium secondary batteries with a larger capacity, the particles forming the columnar structures preferably have a diameter from 10 nm to 1000 nm or 1 nm to 1000 nm. The diameter of the particles may be 15 nm or more, 20 nm or more, or 30 nm or more, and 100 nm or less, 90 nm or less, 80 nm or less, or 70 nm or less.

In view of applicability of the silicon film to electrochemical storage devices such as a lithium secondary battery, the silicon film of the present invention is preferably formed in contact with a substrate. The material for the substrate includes metals. More specifically, the material for the substrate preferably comprises at least one element selected from the group consisting of copper, nickel, iron, cobalt, chromium, manganese, molybdenum, niobium, tungsten, titanium and tantalum; more preferably is at least one element selected from the group consisting of copper, nickel and iron; still more preferably is copper. Stainless steel is also a preferable material.

The substrate preferably has a small thickness, and is preferably a metal foil, and more preferably a copper foil. Among the copper foils, a copper foil having a roughened surface is preferable. Such a copper foil includes an electrolytic copper foil. For example, an electrolytic copper foil is one obtained by immersing a metallic drum into an electrolytic solution containing copper ions dissolved therein, spinning the drum and applying an electric current to deposit copper on the surface of the drum, and pealing off the resultant copper film from the drum surface. One or both surfaces of the electrolytic copper foil may be further roughened or surface-treated. A copper foil having a roughened surface, which is obtained by depositing copper on a surface of a rolled copper foil through electrolysis, may also be used.

In the present invention, the columnar structures is made of Si or a Si compound. Examples of the Si compound include Si—Ge alloy.

In the present invention, impurities may be doped into the Si or the Si compound. The impurities include elements such as nitrogen, phosphorus, aluminum, arsenic, boron, gallium, indium, and oxygen.

<Process for Preparing Silicon Film>

The process of the present invention for preparing silicon film is a process for preparing a silicon film on a substrate by vapor deposition using a vapor deposition source made of Si or Si compound, wherein the temperature of the vapor deposition source is 1700 K or higher, the temperature of the substrate is lower than that of the vapor deposition source, and the temperature difference between the vapor deposition source and the substrate is 700 K or larger. According to the process, a high vacuum is not essential, and the silicon film can also be prepared under normal pressure. According to the process of the present invention, the diffusion of Si atoms in parallel direction to the substrate can be suppressed, and the silicon film of the present invention can be prepared. In view of the accelerating the vapor deposition rate, the temperature of the vapor deposition source is preferably 1800 K or higher. A silicon film obtained by the process of the present invention has the same effects as the silicon film of the present invention. The upper limit temperature of the vapor deposition source is usually around 2300 K.

In the process of the present invention for preparing a silicon film, the distance (D) between the vapor deposition source and the substrate is preferably shorter than the minimum diameter (P) of the substrate, the minimum diameter (P) being determined by viewing the substrate from the perpendicular direction. Then, the growth rate of the film, i.e., the production rate of the film can be improved. In the process of the present invention for preparing a silicon film, even if the substrate is arranged in parallel to the vapor deposition source and Si atoms come from various directions, the silicon film having columnar structures can be obtained.

In the process of the present invention for preparing a silicon film, the mean free path (λ) of Si atoms represented by the following formula is preferably shorter than the distance (D) between the vapor deposition source and the substrate. Thus, the silicon film of the present invention can be easily prepared, and the generation of silicon flat film is further suppressed.

λ=kT/(2^{1/2}σp)

wherein
k=1.38×10⁻²³ (J/K) (Boltzmann constant)
T=temperature (K)
p=pressure (Pa)
σ=πd² (collision cross-sectional area) (in case of Si and Ar, the collision diameter d is 0.35 nm)

This means that the pressure is different from a pressure in a conventional vacuum vapor deposition. In a conventional vacuum vapor deposition (pressure: about 0.001 Pa), the mean free path (λ) of Si atoms is larger than the distance (D) between the vapor deposition source and the substrate.

In particular, if the mean free path (λ) of Si atoms is 1/10 or shorter of the distance (D) between the vapor deposition source and the substrate, the resultant silicon film has the columnar structures being a structure of connected particles, especially connected particles with a diameter from 10 nm to 1000 nm.

In the process of the present invention for preparing a silicon film, the film growth rate is preferably from 0.1 μm/min to 200 μm/min. If the duration of the vapor deposition is set to 0.1 min to 10 min, a silicon film with a practically useful thickness can be prepared.

The substrate used in the process of the present invention for preparing a silicon film is similar to the substrate described above, and thus the description is omitted here.

<Silicon-Film Vapor-Deposition Equipment>

The silicon-film vapor-deposition equipment of the present invention is an equipment for vapor-depositing a silicon film on a substrate by using a vapor deposition source made of Si or a Si compound, the equipment comprising means for heating the vapor deposition source to 1700 K or higher, and means for cooling the substrate to make the temperature of the substrate lower than the temperature of the vapor deposition source, and the temperatures can be adjusted such that the temperature difference between the vapor deposition source and the substrate is 700 K or larger. The silicon film of the present invention can be prepared using this equipment.

The equipment of the present invention is preferably capable of being adjusted such that the minimum diameter (P) of the substrate is larger than distance (D) between the vapor deposition source and the substrate, the minimum diameter (P) being determined by viewing the substrate from the perpendicular direction. In addition, preferably, the equipment comprises a carrier-gas supplying means, and is capable of conducting vapor-deposition under a condition wherein the mean free path (λ) of Si atoms is shorter than the distance (D) between the vapor deposition source and the substrate. The carrier gas can be argon. The equipment is preferably capable of setting the growth rate of the film to the range of 0.1 μm/min to 200 μm/min. The equipment is preferably capable of setting the duration of the vapor deposition to the range of 0.1 min to 10 min.

<Electrode Comprising the Silicon Film>

The electrode comprising the silicon film of the present invention can be suitably used as an electrode of electrochemical storage devices such as lithium secondary batteries. In particular, the electrode comprising the silicon film of the present invention can be very suitably used as a negative electrode of lithium secondary batteries. In the present invention, the substrate can also function as a current collector.

<Lithium Secondary Battery>

As a representative example of the lithium secondary battery of the present invention, the process for preparing the lithium secondary battery, wherein an negative electrode having a copper foil as the substrate and the silicon film formed thereon is used as a negative electrode, is described below.

The lithium secondary battery can be prepared by laminating or laminating and rolling a separator, the negative electrode above, a separator and a positive electrode to form an electrode group, housing the electrode group in a cell casing such as a cell can, and then pouring an electrolyte solution thereinto.

Examples of the shape of the electrode group include a shape that gives a cross section of a circular shape, an elliptical shape, a rectangular shape, a corner-rounded rectangular shape or the like, when the electrode group is cut in the direction perpendicular to the winding axis. Examples of the shape of the battery include a paper shape, a coin shape, a cylinder shape, and a square shape.

<Lithium Secondary Battery—Positive Electrode>

The positive electrode may be any electrode capable of being doped and undoped with lithium ions at higher potential than a negative electrode. The positive electrode can be prepared by known methods. Specifically, the positive electrode is prepared by loading, on a positive electrode current collector, a positive electrode mixture containing a positive electrode active material, an electrically conductive material and a binder. Examples of the electrically conductive materials include a carbonaceous material. Examples of the binder include a thermoplastic resin. Examples of the positive electrode current collector include Al.

<Lithium Secondary Battery—Separator>

The separator above may be any separator selected from known separators. For examples, films in the form of a porous film, a nonwoven fabric or a woven fabric made of a material, such as a polyolefin resin including polyethylene and polypropylene, and a fluororesin, can be used as the separator.

<Lithium Secondary Battery—Electrolytic Solution>

The electrolytic solution above may be selected from known electrolytic solutions. The electrolytic solution generally contains an electrolyte and an organic solvent. Usable electrolytic solutions can be obtained by dissolving electrolyte of lithium salts, such as LiPF₆, in an organic solvent, such as propylene carbonate (PC), ethylene carbonate (EC), dimethyl carbonate (DMC) and ethylmethyl carbonate (EMC).

### EXAMPLES

The following examples are used to illustrate the present invention, but the present invention is not limited thereto.

### Example 1

### Preparation of Silicon Film

Tungsten boat of 80 mm×6 mm was installed in a chamber, and then a silicon piece (purity of 99.99% or more) HF-treated with 5% to 10% HF solution was loaded on the boat, as a vapor deposition source. The size of the vapor deposition source becomes 80 mm×6 mm, since the silicon piece melts to spread on the boat due to heating.

Stainless foil (SUS304, 30 mm in diameter) was set above the tungsten boat to be a substrate (a current collector). The stainless foil was faced parallel to the silicon plate. The distance between the vapor deposition source and the substrate was set to 25 mm, which was shorter than 30 mm of the minimum diameter of the substrate. The stainless foil was intimately attached to and fixed on a surface of a cooling block which can be cooled with use of a water-cooling tube.

The chamber was vacuumed to 10⁻⁵ Pa by a turbo molecular pump, and then argon gas was introduced at 10 sccm to set the pressure of the chamber to 13.3 Pa (0.1 Torr).

The mean free path (λ) of Si atoms can be calculated by using the formula λ=kT/(2^{1/2}σp) from kinetic theory of molecules. In this situation, Boltzmann constant k=1.38×10⁻²³ J/K, temperature T=300 K, pressure p=13.3 Pa and collision cross-section σ=πd². Therefore, if collision diameter “d” between Si and Ar is 0.35 nm, the mean free path (λ) is calculated to 0.57 mm.

After the pressure got stable, water flow was started to cool the block. And then, a current of 200 A at 2 V was applied to the tungsten boat in order to heat the tungsten boat to 2070 K and to melt the silicon piece, such that the stainless foil was subjected to vapor deposition for one minute (film growth rate: 0.6 μm/min) and a silicon film with 0.6 μm thickness was obtained. The temperature of the stainless foil was 330 K.

### Structure of Silicon Film

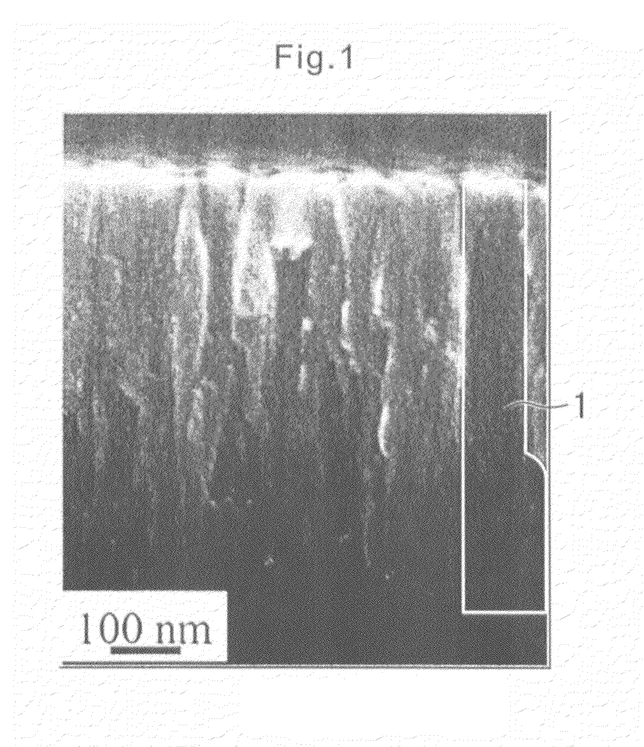

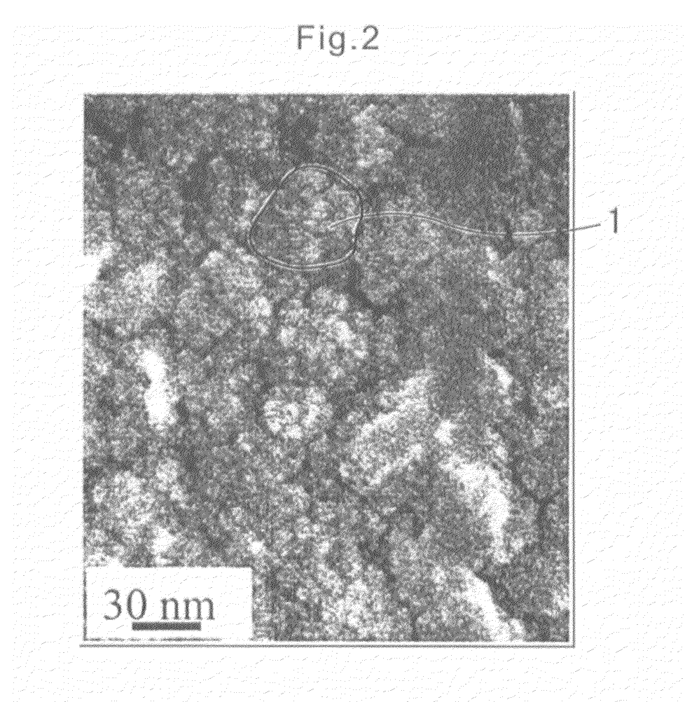

The cross-sectional SEM image of the resultant silicon film is shown in FIG. 1, and the surface SEM image of the resultant silicon film is shown in FIG. 2. FIG. 1 shows that the film of the present invention has columnar structures (1). FIG. 2 shows columnar structures (1). According to FIGS. 1 and 2, it can be confirmed that the columnar structures (1) grow-in the film thickness direction, and that the aspect ratio thereof is 5 or more, and a part of the columnar structures (1) has a aspect ratio of 20 or more.

### Preparation of Lithium Secondary Battery TC1)

Negative electrode AE1 was obtained by cutting the silicon film formed on the substrate to the size of 1×1 cm. The negative electrode AE1 was dried at a temperature of 120° C. in a vacuum oven for 6 hours. After drying, it was transported into an argon gas-substituted glove box to immerse in an electrolytic solution (1M LiPF₆/EC+EMC (weight ratio EC:EMC=3:7)).

A Li metal piece of 1.5×1.5 cm was placed in HS cell (Hohsen Corporation). Thereafter, a separator (Celgard 2500) cut to the size of 2×2 cm was placed in the cell, and then the electrolytic solution was poured into the cell. Lithium secondary battery TC1 was then assembled by disposing the negative electrode AE1 with the vapor-deposited silicon surface of the negative electrode AE1 facing to the separator.

(Charge and Discharge Test)

A rated capacity of lithium secondary battery TC1 was supposed to the theoretic capacity thereof of 4200 mAh/g. Charge and discharge test was carried out by repeating charge and discharge under the condition of a constant current/constant voltage charge at 0.1 C and 0 V for 8 hours (in this case, electrode AE1 was doped with Li), and a constant current discharge at 0.1 C and cutoff voltage of 2 V (in this case, electrode AE1 was undoped with Li).

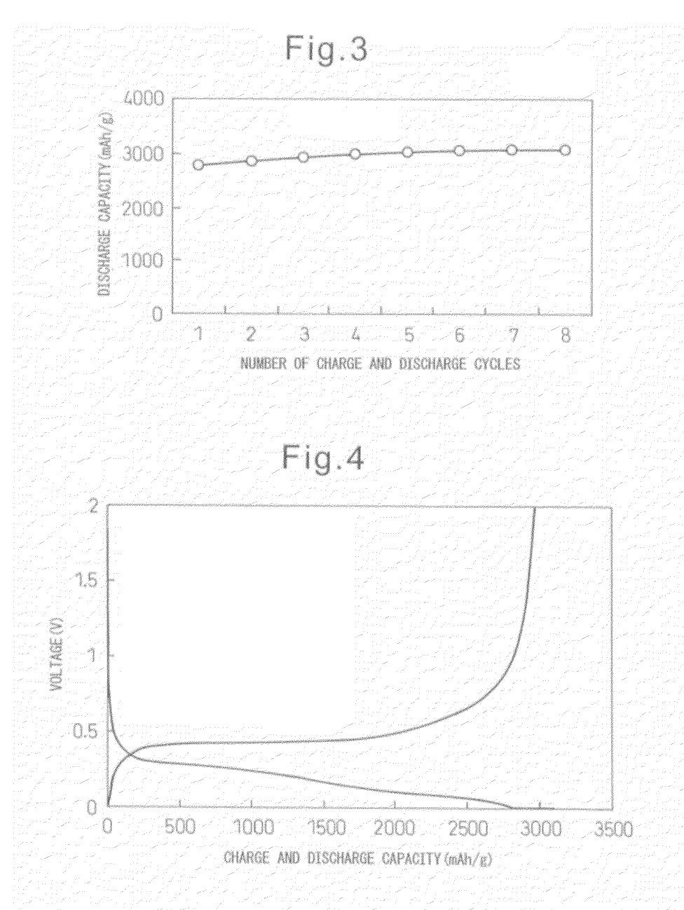

The results of the charge and discharge tests are shown in FIGS. 3 and 4. These figures show that the negative electrode having the silicon film of the present invention provides a lithium secondary battery with good secondary battery properties, such as cycle characteristics.

### Example 2

### Preparation of Silicon Film

Except for the silicon loading amount, the same preparation method as Example 1 was carried out to obtain a silicon film with 0.8 μm thickness.

### Preparation and Charge and Discharge Test of Lithium Secondary Battery TC2

Except for the use of this silicon film, in the same manner as Example 1, the lithium secondary battery TC2 was prepared, and the charge and discharge test was carried out by repeating charge and discharge.

The results of the charge and discharge test are shown in FIG. 5. FIG. 5 shows that the negative electrode having the silicon film of the present invention provides a lithium secondary battery with good secondary battery properties, such as cycle characteristics.

### Example 3

### Preparation of Silicon Film

Except for setting the pressure of the chamber during the vapor deposition to 133 Pa (1 Torr, the mean free path of Si atoms is calculated to 0.057 mm in this case), the same preparation method as Example 1 was carried out to obtain a silicon film with 0.4 μm thickness.

### Preparation and Charge and Discharge Test of Lithium Secondary Battery TC3

Except for the use of this silicon film, in the same manner as Example 1, the lithium secondary battery TC3 was prepared, and the charge and discharge test was carried out by repeating charge and discharge.

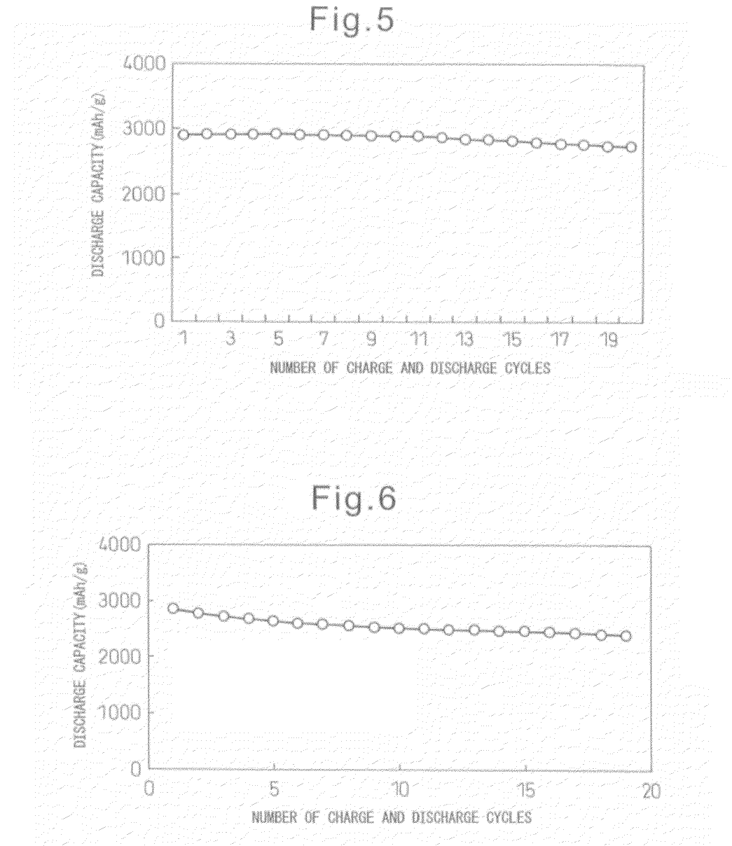

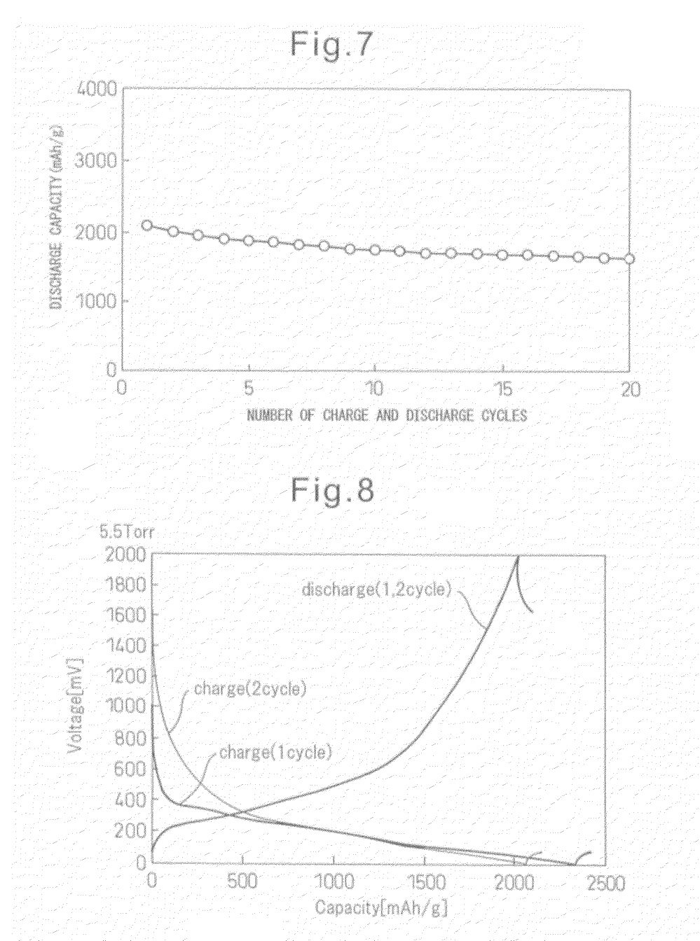

The results of the charge and discharge test are shown in FIG. 6. FIG. 6 shows that the negative electrode having the silicon film of the present invention provides a lithium secondary battery with good secondary battery properties, such as cycle characteristics.

### Example 4

### Preparation of Silicon Film

Except for the silicon-loading amount, the same preparation method as Example 3 was carried out to obtain a silicon film with 2.0 μm thickness.

### Preparation and Charge and Discharge Test of Lithium Secondary Battery TC4

Except for the use of this silicon film, in the same manner as Example 3, the lithium secondary battery TC4 was prepared, and the charge and discharge test was carried out by repeating charge and discharge.

From the results of the charge and discharge test, it was found that the discharge capacity does, not change even after the cycle is repeated 10 times or more, and that the resultant battery exhibits good secondary battery properties, such as cycle characteristics.

### Example 5

### Preparation of Silicon Film

Except for setting the pressure of the chamber during vapor deposition to 732 Pa (5.5 Torr, the mean free path of Si atoms is calculated to 0.010 mm in this case), the same preparation method as Example 1 was carried out to obtain a silicon film with 0.25 μm thickness.

### Preparation and Charge and Discharge Test of Lithium Secondary Battery TC5

Except for the use of this silicon film, in the same manner as Example 1, the lithium secondary battery TC5 was prepared, and the charge and discharge test was carried out by repeating charge and discharge.

The results of the charge and discharge test are shown in FIGS. 7 and 8. These figures show that the negative electrode having the silicon film of the present invention provides a lithium secondary battery with good secondary battery properties, such as cycle characteristics.

### Example 6

### Preparation of Silicon Film

Except for the silicon-loading amount and the use of Cu foil as the substrate, the same preparation method as Example 1 was carried out to obtain a silicon film with 2.5 μm thickness.

### Preparation and Charge and Discharge Test of Lithium Secondary Battery TC6

Except for the use of this silicon film, in the same manner as Example 1, the lithium secondary battery TC6 was prepared, and the charge and discharge test was carried out by repeating charge and discharge.

From the results of the charge and discharge test, it was found that the discharge capacity does not change even after the cycle is repeated 10 times or more, and that the battery exhibits good secondary battery properties, such as cycle characteristics.

### Example 7

### Preparation of Silicon Film

Except for the silicon-loading amount, the same preparation method as Example 6 was carried out to obtain a silicon film with 3.7 μm thickness. The silicon film was then annealed for 10 minutes in an argon gas atmosphere at the normal pressure.

### Structure of Silicon Film

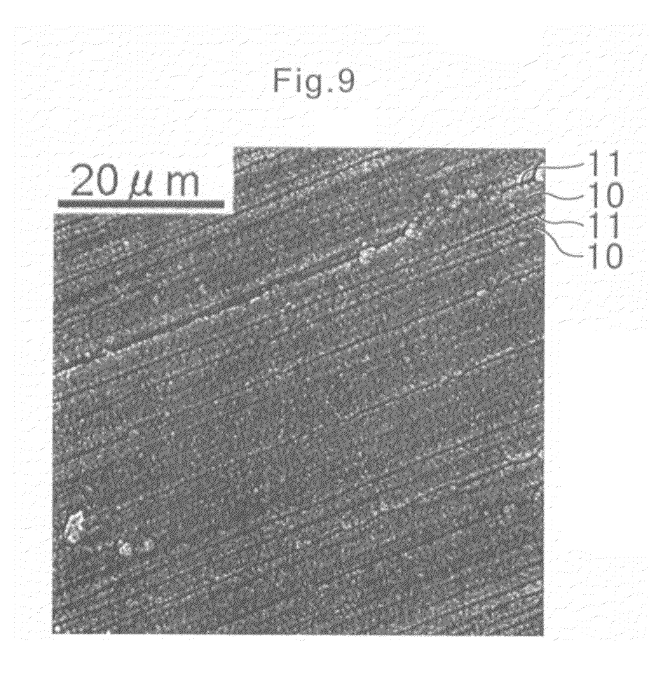

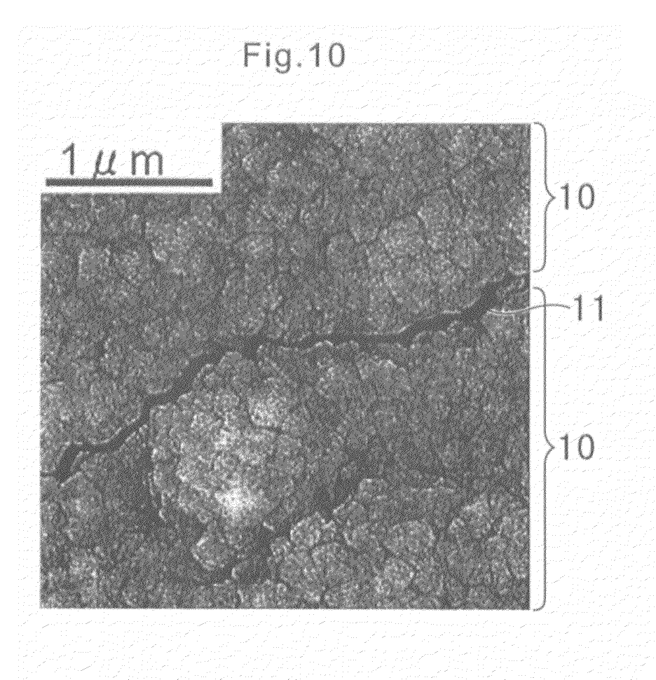

The surface SEM images of the resultant silicon film are shown in FIG. 9 at a low magnification, and in FIG. 10 at a high magnification. FIG. 9 shows that cracks (11) confirming to the irregularity of the Cu foil surface are formed at intervals of 1 μm to 3 μm between columnar aggregates (10) each of which is aggregates of the columnar structures. FIG. 10 shows that the silicon film is made of columnar structures (1) having diameters of 30 nm to 200 nm. Also, FIG. 10 shows that the widths of the cracks (11) between columnar aggregates (10), each of which is aggregates of the columnar structures, are about 30 nm.

### Preparation and Charge and Discharge Test of Lithium Secondary Battery TC7

Except for using this silicon film, in the same manner as Example 1, the lithium secondary battery TC7 is prepared, and the charge and discharge test was carried out by repeating charge and discharge.

From the results of the charge and discharge test, it was found that the discharge capacity does not change even after the cycle is repeated 10 times or more, and that the battery exhibits good secondary battery properties, such as cycle characteristics.

### EXPLANATIONS OF LETTERS or NUMERALS

1 Columnar structures
10 Columnar aggregates
11 Cracks between columnar aggregates

1. A silicon film, comprising a columnar aggregate which is an aggregate of columnar structures made of Si or a Si compound.

2. The silicon film according to claim 1, wherein side faces of the columnar structures are in contact with each other to form the columnar aggregate.

3. The silicon film according to claim 1, wherein the columnar structures grow in the direction of thickness of the silicon film.

4. The silicon film according to claim 1, wherein the aspect ratio of the columnar structures is 20 or more.

5. The silicon film according to claim 1, having a plurality of the columnar aggregates.

6. The silicon film according to claim 1, wherein the diameter of the columnar structures is from 10 nm to 100 nm and the film thickness is from 0.2 μm to 100 μm.

7. The silicon film according to claim 1, wherein gaps of 0.3 nm to 10 nm are present between the columnar structures in parallel to the columnar structures.

8. The silicon film according to claim 1, having cracks of 0.01 μm to 3 μm width between the columnar aggregates in parallel to the columnar aggregates, and the distance between the cracks is from 1 μm to 100 μm.

9. The silicon film according to claim 1, wherein the columnar structures are polycrystalline or amorphous.

10. A silicon film, comprising a columnar aggregate which is an aggregate of columnar structures made of Si or a Si compound, the columnar structures having a structure of particles connected in a columnar shape.

11. The silicon film according to claim 10, wherein the diameter of the particles is from 10 nm to 1000 nm.

12. The silicon film according to claim 10, having a plurality of the columnar aggregates.

13. The silicon film according to claim 1, which is formed in contact with a substrate.

14. The silicon film according to claim 13, wherein the material of the substrate comprises at least one element selected from the group consisting of copper, nickel, iron, cobalt, chromium, manganese, molybdenum, niobium, tungsten, titanium and tantalum.

15. A process for preparing a silicon film on a substrate by vapor deposition using a vapor deposition source made of Si or a Si compound, wherein the temperature of the vapor deposition source is 1700 K or higher, the temperature of the substrate is lower than that of the vapor deposition source, and the temperature difference between the vapor deposition source and the substrate is 700 K or larger.

16. The process for preparing the silicon film according to claim 15, wherein the distance (D) between the vapor deposition source and the substrate is shorter than the minimum diameter (P) of the substrate, the minimum diameter (P) being determined by viewing the substrate from the perpendicular direction.

17. The process for preparing the silicon film according to claim 15, wherein the mean free path (λ) of Si atoms is shorter than the distance (D) between the vapor deposition source and the substrate.

18. The process for preparing the silicon film according to claim 15, wherein the mean free path (λ) of Si atoms is 1/10 or shorter of the distance (D) between the vapor deposition source and the substrate.

19. The process for preparing the silicon film according to claim 15, wherein the growth rate of the film is from 0.1 μm/min to 200 μm/min.

20. The process for preparing the silicon film according to claim 15, wherein the material of the substrate comprises at least one element selected from the group consisting of copper, nickel, iron, cobalt, chromium, manganese, molybdenum, niobium, tungsten, titanium and tantalum.

21. A silicon-film vapor-deposition equipment for vapor-depositing a silicon film on a substrate by using a vapor deposition source made of a Si or a Si compound,
wherein the equipment comprises:
means for heating the vapor deposition source to a temperature of 1700 K or higher, and
means for cooling the substrate to make the temperature of the substrate lower than that of the vapor deposition source, and
the temperatures of the vapor deposition source and the substrate can be adjusted such that the difference therebetween becomes 700 K or larger.

22. The silicon-film vapor-deposition equipment according to claim 21, wherein the minimum diameter (P) of the substrate can be set to longer than the distance (D) between the vapor deposition source and the substrate, the minimum diameter (P) being determined by viewing the substrate from the perpendicular direction.

23. The silicon-film vapor-deposition equipment according to claim 21, further comprising a carrier gas supplying means, and capable of conducting a vapor deposition under a condition wherein the mean free path (λ) of Si atoms is shorter than the distance (D) between the vapor deposition source and the substrate.

24. The silicon-film vapor-deposition equipment according to claim 21, capable of adjusting the growth rate of the film to the range of 0.1 to 200 μm/min.

25. An electrode comprising the silicon film according to claim 1.

26. The electrode according to claim 25, wherein the silicon film is formed in contact with a metal substrate.

27. A lithium secondary battery, comprising the electrode according to claim 25 as a negative electrode.

28. The silicon film according to claim 10, which is formed in contact with a substrate.

29. The silicon film according to claim 28, wherein the material of the substrate comprises at least one element selected from the group consisting of copper, nickel, iron, cobalt, chromium, manganese, molybdenum, niobium, tungsten, titanium and tantalum.

30. An electrode comprising the silicon film according to claim 10.

31. The electrode according to claim 30, wherein the silicon film is formed in contact with a metal substrate.

32. A lithium secondary battery, comprising the electrode according to claim 31 as a negative electrode.
